(19) United States
(12) Patent Application Publication
(10) Pub. No.: US 2025/0159806 A1
(43) Pub. Date: May 15, 2025

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventor: Yongjin Oh, Suwon-si (KR)

(73) Assignee: SAMSUNG ELECTRO-MECHANICS CO., LTD., Suwon-si (KR)

(21) Appl. No.: 18/782,242

(22) Filed: Jul. 24, 2024

(30) Foreign Application Priority Data
Nov. 10, 2023 (KR) 10-2023-0155285

(51) Int. Cl. H05K 1/11; H05K 3/40; H05K 3/46

(52) U.S. Cl. CPC H05K 1/112; H05K 3/4007; H05K 3/4038; H05K 3/4644

(57) ABSTRACT

A printed circuit board according to an embodiment may include an insulating layer; a wiring layer buried in the insulating layer; and a pad portion protruding from the insulating layer in a height direction, in which the pad portion may include a first portion and a second portion disposed below the first portion in the height direction, a width of the second portion may be greater than that of the first portion of the pad portion in a plane direction perpendicular to the height direction, a side wall of the second portion may have a curved shape in the height direction, and the side wall of the second portion may be buried in the insulating layer.

### CROSS-REFERENCE TO RELATED APPLICATION

This application claims priority to and the benefit of Korean Patent Application No. 10-2023-0155285 filed in the Korean Intellectual Property Office on Nov. 10, 2023, the entire contents of which are incorporated herein by reference.

### BACKGROUND

### 1. Field

The present disclosure relates to a printed circuit board and manufacturing method thereof.

### 2. Description of the Related Art

As electronic devices in the IT field, including mobile phones, become smaller, a size of metal posts formed on a printed circuit board on which electronic components are mounted is also becoming smaller.

As the size of the metal posts on the printed circuit board decreases, the metal posts may become separated from the printed circuit board and disappear.

### SUMMARY

The present disclosure attempts to provide a printed circuit board and manufacturing method thereof capable of preventing a pad portion from being separated from the printed circuit board and lost.

However, problems to be solved by the embodiments are not limited to the above-described problems and may be variously extended in the range of technical ideas included in the embodiments.

According to an aspect of this disclosure, a printed circuit board may include an insulating layer; a wiring layer buried in the insulating layer; and a pad portion protruding from the insulating layer along a height direction, in which the pad portion may include a first portion and a second portion disposed below the first portion along the height direction, a width of the second portion may be greater than that of the first portion of the pad portion along a plane direction perpendicular to the height direction, a side wall of the second portion may have a curved shape along the height direction, and the side wall of the second portion may be buried in the insulating layer.

According to another aspect of this disclosure, a printed circuit board may include: an insulating layer; a wiring layer buried in the insulating layer; and a pad portion protruding from the insulating layer along a height direction, in which the pad portion may include a first portion, a second portion disposed below the first portion along the height direction and buried in the insulating layer, and a third portion disposed above the first portion along the height direction and protruding from the insulating layer, a width of the second portion may be greater than that of the first portion of the pad portion along a plane direction perpendicular to the height direction, and a width of the third portion may be greater than that of the first portion of the pad portion along the plane direction

At least a portion of the first portion of the pad portion may protrude from the insulating layer along the height direction.

The pad portion may further include a third portion disposed above the first portion along the height direction, and a width of the third portion may be greater than that of the first portion of the pad portion along the plane direction.

At least a portion of the first portion and the third portion of the pad portion may protrude from the insulating layer along the height direction.

The side wall of the pad portion may have a shape depressed inwardly of the pad portion along the height direction.

The insulating layer may have a via hole overlapping the pad portion, and the pad portion may contact a via disposed in the via hole.

The insulating layer may include a first insulating layer and a second insulating layer disposed below the first insulating layer, and the wiring layer may include a first wiring layer buried in the second insulating layer and a second wiring layer disposed below the second insulating layer.

The first insulating layer may have a first via hole, the second insulating layer may have a second via hole, the first wiring layer and the pad portion may be connected to each other through a first via disposed in the first via hole, and the first wiring layer and the second wiring layer may be connected to each other through a second via disposed in the second via hole.

The printed circuit board may further include a passivation layer disposed below the second insulating layer, in which the passivation layer may expose at least a portion of the second wiring layer.

The printed circuit board may further include a surface treatment layer disposed above the pad portion.

A manufacturing method of a printed circuit board may include: stacking a metal layer; forming a photoresist pattern on the metal layer; forming a pad portion by etching the metal layer using a photoresist pattern as an etch mask; stacking an insulating layer burying the pad portion; forming a wiring layer buried in the insulating layer; and removing a portion of the insulating layer to expose a portion of the pad portion from the insulating layer along a height direction, in which the pad portion may include a first portion and a second portion disposed below the first portion along the height direction, a width of the second portion may be formed to be greater than that of the first portion of the pad portion along a plane direction perpendicular to the height direction, a side wall of the second portion may be formed to have a curved shape along a height direction, and the side wall of the second portion may be buried in the insulating layer.

According to the embodiments, it is possible to provide a printed circuit board and manufacturing method thereof capable of preventing a pad portion from being separated from the printed circuit board and lost.

However, it is obvious that the effects of the embodiments are not limited to the above-described effects, and may be variously extended without departing from the spirit and scope of this disclosure.

### BRIEF DESCRIPTION OF THE DRAWINGS

FIG. 1 is a cross-sectional view of a printed circuit board according to an embodiment.

FIG. 2 is an enlarged view of a portion of FIG. 1.

FIGS. 3 to 19 are cross-sectional views illustrating a manufacturing method of a printed circuit board according to an embodiment.

### DETAILED DESCRIPTION

Hereinafter, embodiments will be described in detail with reference to the accompanying drawings so that those skilled in the art to which this disclosure pertains may easily this disclosure. However, this disclosure may be implemented in various different forms and is not limited to embodiments provided herein.

Portions unrelated to the description will be omitted in order to obviously describe this disclosure, and similar components will be denoted by the same reference numerals throughout the present specification.

Further, it should be understood that the accompanying drawings are provided only in order to allow embodiments of the present disclosure to be easily understood, and the spirit of the present disclosure is not limited by the accompanying drawings, but includes all the modifications, equivalents, and substitutions included in the spirit and the scope of the present disclosure.

In addition, the size and thickness of each component illustrated in the drawings are arbitrarily indicated for convenience of description, and this disclosure is not necessarily limited to the illustrated those. In the drawings, the thickness of layers, films, panels, regions, etc., are exaggerated for clarity. In addition, in the accompanying drawings, thicknesses of some of layers and regions have been exaggerated for convenience of explanation.

In addition, it will be understood that when an element such as a layer, film, region, or substrate is referred to as being “on” another element, it can be “directly on” the other element or intervening elements may also be present. In contrast, when an element is referred to as being “directly on” another element, there are no intervening elements present. In addition, when an element is referred to as being “on” a reference element, it can be positioned on or beneath the reference element, and is not necessarily positioned “on” the reference element in an opposite direction to gravity.

In addition, unless explicitly described to the contrary, the word “comprise”, and variations such as “comprises” or “comprising”, will be understood to imply the inclusion of stated elements but not the exclusion of any other elements. Further, throughout the specification, the word “plan view” refers to a view when a target is viewed from the top, and the word “cross-sectional view” refers to a view when a cross section of a target taken along a vertical direction is viewed from the side.

Also, throughout the specification, when it is said to be “connected”, this does not mean that two or more components are directly connected, but means that two or more components are indirectly connected through another component, that two or more components are physically connected as well as electrically connected, or that two or more components are referred to by different names depending on their location or function, but are integral.

Hereinafter, embodiments and medications in the present disclosure will be described in detail with reference to the drawings.

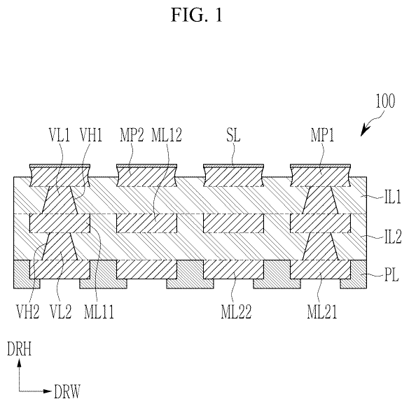

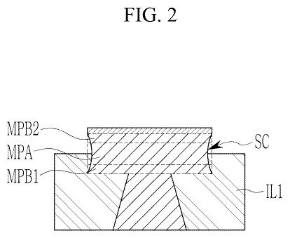

Referring to FIGS. 1 and 2, a printed circuit board according to an embodiment will be described. FIG. 1 is a cross-sectional view of a printed circuit board according to an embodiment. FIG. 2 is an enlarged view of a portion of FIG. 1.

Referring to FIG. 1, a printed circuit board 100 according to the present embodiment may include a plurality of stacked insulating layers IL, a plurality of wiring layers ML buried in the plurality of insulating layers IL or disposed on a portion of the plurality of insulating layers IL, a plurality of vias VL disposed within a plurality of via holes VH of the plurality of insulating layers IL, a plurality of pad portions MP, and a passivation layer PL.

The plurality of insulating layers IL may include a first insulating layer IL1 and a second insulating layer IL2 that overlap along a height direction DRH. The first insulating layer IL1 and the second insulating layer IL2 are made of a thermosetting resin such as an epoxy resin, a thermoplastic resin such as polyimide, or a resin impregnated with a reinforcing material such as glass fiber or inorganic filler, for example, prepreg, but the embodiment is not limited thereto. In the illustrated embodiment, the plurality of insulating layers IL include a first insulating layer IL1 and a second insulating layer IL2, but the embodiment is not limited thereto and may further include additional insulating layers.

The plurality of wiring layers ML may include a first wiring layer ML11 and a second wiring layer ML12 buried in the second insulating layer IL2, and a third wiring layer ML21 and a fourth wiring layer ML22 disposed on the second insulating layer IL2.

The plurality of vias VL may include a first via VL1 disposed within a first via hole VH1 formed in the first insulating layer IL1 and a second via VL2 disposed within a second via hole VH2 formed in the second insulating layer IL2.

The plurality of pad portions MP may include a first pad portion MP1 and a second pad portion MP2 partially buried in the first insulating layer IL1.

A portion of the first wiring layer ML11 and a portion of the first pad portion MP1 may be connected to each other through the first via VL1, and a portion of the first wiring layer ML11 and a portion of the third wiring layer ML21 may be connected to each other through the second via VL2. In the illustrated embodiment, the first via VL1 and the second via VL2 are illustrated as having a tapered shape whose diameter increases downward along the height direction DRH, but the embodiment is not limited thereto.

The plurality of wiring layers ML, the plurality of vias VL, and the plurality of pad portions MP may include a conductive metal, and for example, may include copper, but the embodiment is not limited thereto.

The passivation layer PL is disposed below the second insulating layer IL2 and may expose portions of the third wiring layer ML21 and the fourth wiring layer ML22. The passivation layer PL may be a photoresist layer, but the embodiment is not limited thereto.

The third wiring layer ML21 and the fourth wiring layer ML22 may be electrically connected to an external layer.

A surface treatment layer SL may be positioned on the first pad portion MP1 and the second pad portion MP2.

Referring to FIG. 2 along with FIG. 1, the pad portion MP of the printed circuit board 100 according to the embodiment will be described in more detail.

The pad portion MP of the printed circuit board 100 according to the embodiment may have a side wall SC depressed inwardly of the pad portion.

Along a plane direction DRW perpendicular to the height direction DRH, the pad portion MP may include 1) a relatively narrow middle portion MPA, 2) a lower portion MPB1 connected to the middle portion MPA, disposed below the middle portion MPA along the height direction DRH, and having a greater width than that of the middle portion MPA, and 3) an upper portion MPB2 disposed above the middle portion MPA and having a greater width than that of the middle portion MPA. The lower portion MPB1 may be buried in the insulating layer IL, and the upper portion MPB2 may protrude from the insulating layer IL.

The side wall SC of the lower portion MPB1, which has a greater width than that of the middle portion MPA, may have a curved shape along the height direction DRH.

Among the side walls SC of the pad portion MP, at least the side wall SC of the lower portion MPB1 may be covered with the insulating layer IL. Among the side walls SC of the pad portion MP, portions of the side wall SC of the lower portion MPB1 and the side wall SC of the middle portion MPA may be covered with the insulating layer IL.

According to the printed circuit board 100 according to the embodiment, the pad portion MP includes a relatively narrow middle portion MPA having the side wall SC depressed inwardly of the pad portion, and a lower portion MPB1 and an upper portion MPB2 connected to the middle portion MPA, disposed below and above the middle portion MPA along the height direction DRH and having a greater width than that of the middle portion MPA, and the side wall SC of the lower portion MPB1 may be covered with the first insulating layer IL1. In this way, the relatively widely expanded lower portion MPB1 of the pad portion MP is covered and protected with the insulating layer IL, thereby preventing the pad portion MP from being separated from the printed circuit board and lost.

Accordingly, it is possible to increase contact characteristics with an additional layer connected through the pad portion MP of the printed circuit board 100.

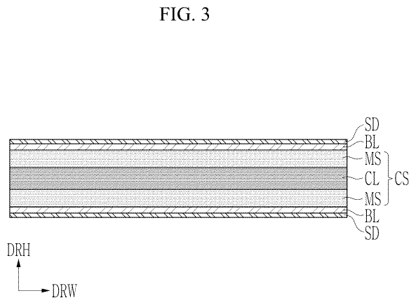

A manufacturing method of a printed circuit board according to an embodiment will be described with reference to FIGS. 3 to 19 along with FIGS. 1 and 2. FIGS. 3 to 19 are cross-sectional views illustrating a manufacturing method of a printed circuit board according to an embodiment.

Referring to FIG. 3, a barrier layer BL and a copper foil layer SD are formed on both surfaces of the carrier substrate CS including a core portion CL and a thin metal layer MS stacked on both sides of the core portion CL.

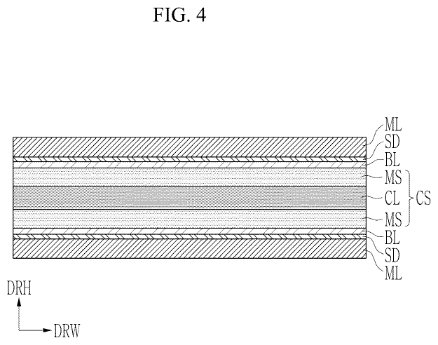

Referring to FIG. 4, a first metal layer ML is formed on the copper foil layer SD disposed on both sides of the carrier substrate CS. The first metal layer ML may be formed on the copper foil layer SD by plating, but the embodiment is not limited thereto.

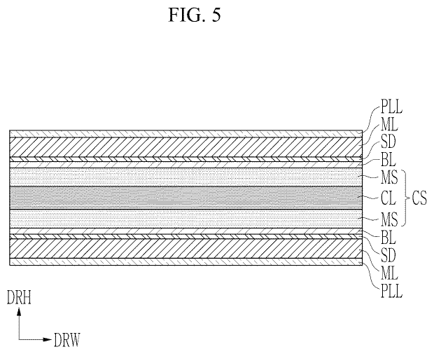

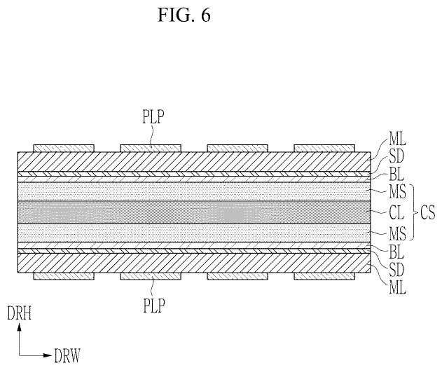

Referring to FIG. 5, a first photo resist layer PLL is stacked on the first metal layer ML disposed on both surfaces of the carrier substrate CS, and as illustrated in FIG. 6, a plurality of photoresist patterns PLP may be formed at a location where the plurality of pad portions MP will be formed.

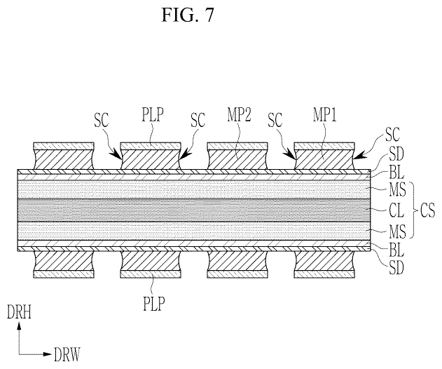

Referring to FIG. 7, the first metal layer ML is etched using the plurality of photo resist patterns PLP as an etch mask to form a first pad portion MP1 and a second pad portion MP2. In this case, the etching conditions may be adjusted so that the plurality of pad portions MP including the first pad portion MP1 and the second pad portion MP2 have the side wall SC depressed inwardly of the pad portion.

As illustrated in FIG. 2, the first pad portion MP1 and the second pad portion MP2 may include the relatively narrow middle portion MPA and the lower portion MPB1 and the upper portion MPB2 connected to the middle portion MPA, disposed below and above the middle portion MPA along the height direction DRH and having a greater width than that of the middle portion MPA.

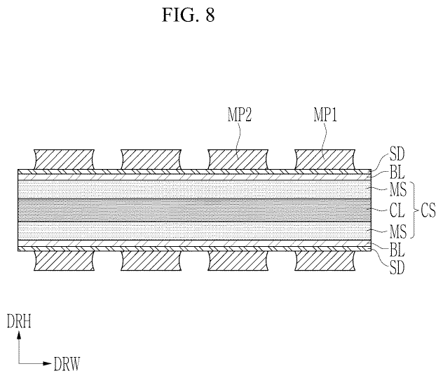

As illustrated in FIG. 8, the plurality of photo resist patterns PLP may be removed.

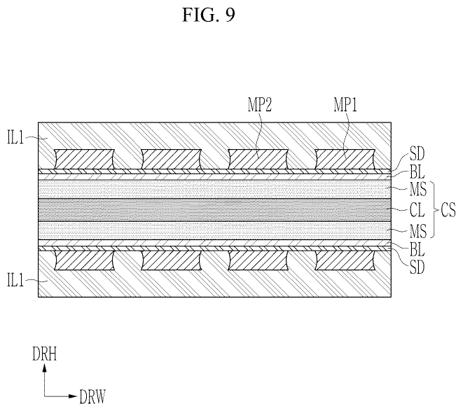

As illustrated in FIG. 9, the first insulating layer IL1 may be stacked so that the plurality of pad portions MP including the first pad portion MP1 and the second pad portion MP2 are buried.

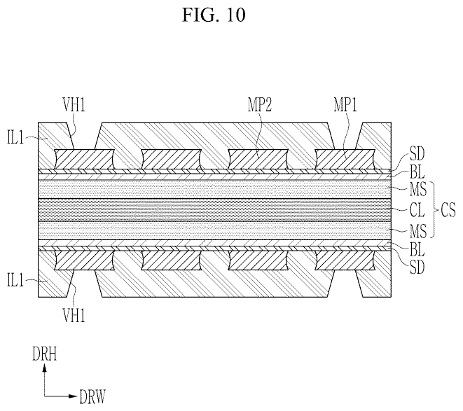

As illustrated in FIG. 10, the first via hole VH1 exposing at least a portion of the first pad portion MP1 may be formed in the first insulating layer IL1.

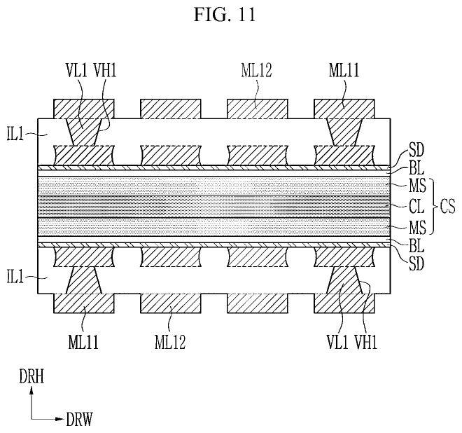

As illustrated in FIG. 11, the first via VL1 is formed in the first via hole VH1 of the first insulating layer IL1, and the first wiring layer ML11 connected to the first via VL1 and the second wiring layer ML12 not connected to the first via VL1 may be formed on the first insulating layer IL1.

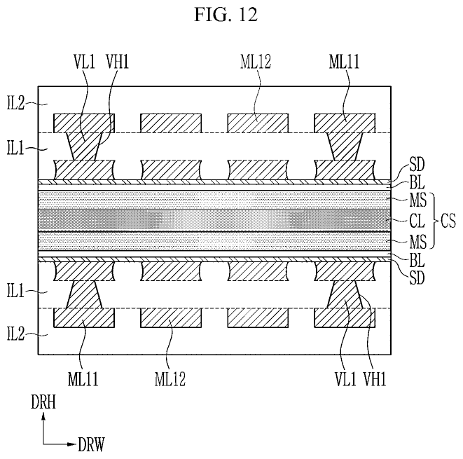

As illustrated in FIG. 12, the second insulating layer IL2 may be stacked on the first insulating layer IL1 so that the first and second wiring layers ML11 and ML12 are buried.

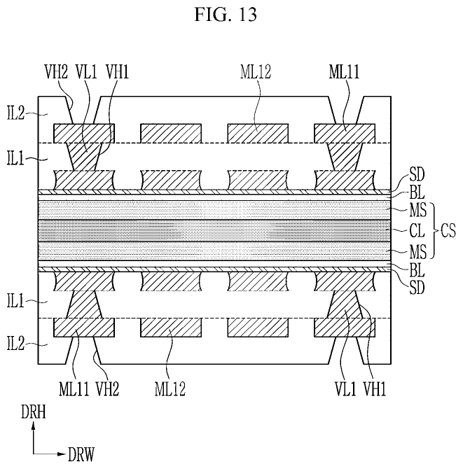

As illustrated in FIG. 13, the second via hole VH2 exposing at least a portion of the first wiring layer ML11 may be formed in the second insulating layer IL2.

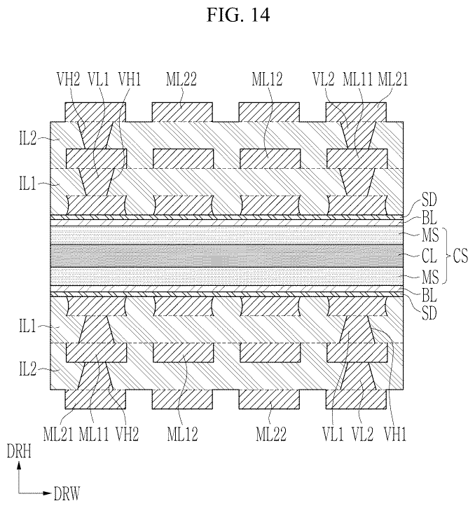

As illustrated in FIG. 14, the second via VL2 may be formed in the second via hole VH2 of the second insulating layer IL2, and a third wiring layer ML21 connected to the second via VL2 and a fourth wiring layer ML22 not connected to the second via VL2 may be formed on the second insulating layer IL2.

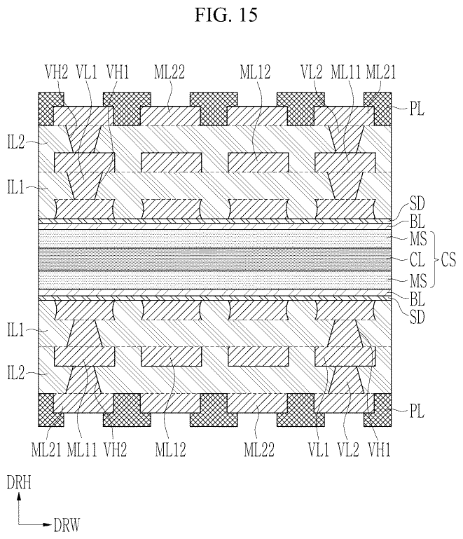

As illustrated in FIG. 15, the passivation layer PL may be formed on the second insulating layer IL2 to expose portions of the third wiring layer ML21 and the fourth wiring layer ML22.

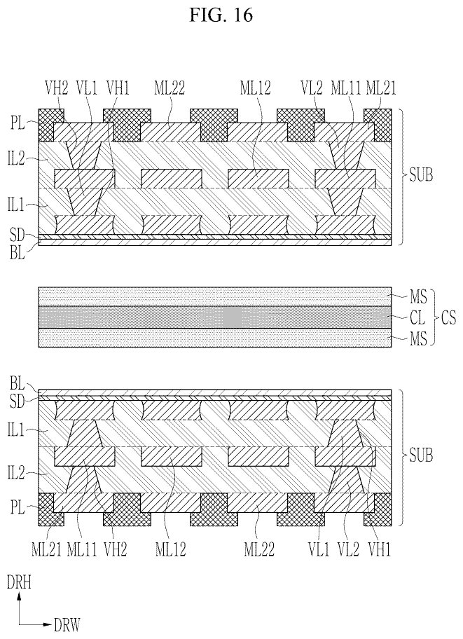

As illustrated in FIG. 16, a substrate portion SUB is peeled from both sides of the carrier substrate CS.

Hereinafter, one substrate portion SUB peeled from the carrier substrate CS will be described.

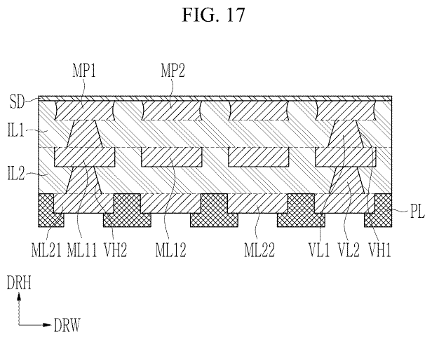

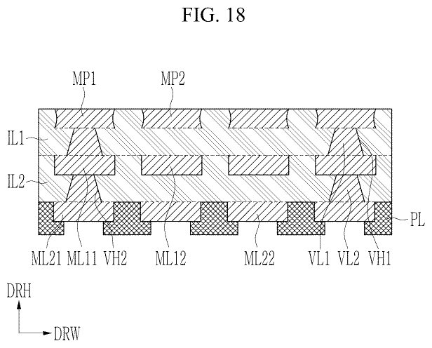

As illustrated in FIG. 17, the barrier layer BL is removed from the substrate portion SUB, and as illustrated in FIG. 18, the copper foil layer SD is removed.

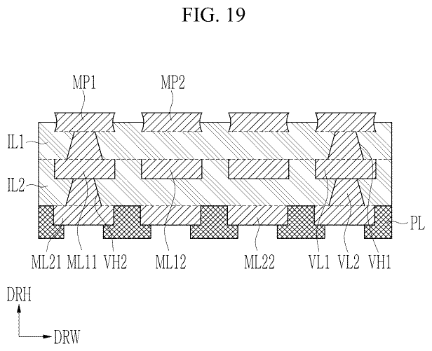

As illustrated in FIG. 19, a portion of the first insulating layer IL1 may be removed, so the first insulating layer IL1 may cover the relatively wide lower portion of the side wall SC of the first pad MP1 and the second pad MP2 and may not cover the upper portion of the side wall SC of the first pad portion MP1 and the second pad portion MP2.

More specifically, the pad portion MP may include the relatively narrow middle portion MPA with the side wall SC depressed inwardly and the lower portion MPB1 and the upper portion MPB2 connected to the middle portion MPA and disposed below and above the middle portion MPA along the height direction DRH, and the relatively widely expanded lower portion MPB1 of the pad portion MP may be covered with the insulating layer IL.

Next, as illustrated in FIG. 1, the surface treatment layer SL may be formed on the surfaces of the first pad portion MP1 and the second pad portion MP2.

The surface treatment layer SL may be formed through any one of ElectroGold plating, immersion gold plating, organic solderability preservative (OSP), immersion tin plating, immersion silver plating, electroless nickel and immersion gold (ENIG) (electroless nickel plating/substitution gold plating), direct immersion gold plating (DIG plating), and hot AirSolder leveling (HASL).

As such, according to the manufacturing method of a printed circuit board according to the embodiment, the pad portion MP may include the relatively narrow middle portion MPA with the side wall SC depressed inwardly, and the lower portion MPB1 and the upper portion MPB2 connected to the middle portion MPA and disposed below and above the middle portion MPA along the height direction DRH, and the relatively widely expanded lower portion MPB1 of the pad portion MP is formed to be covered with the insulating layer IL, thereby preventing the pad portion MP from being separated and lost and improving the contact characteristics with additional layers connected through the pad portion MP of the printed circuit board 100.

Although preferred embodiments have been described above, this disclosure is not limited thereto, and this disclosure can be variously modified within the scope of the claims, the detailed description of this disclosure, and the appended drawings, and it is natural that various modifications also fall within the scope of this disclosure.

### DESCRIPTION OF SYMBOLS

IL, IL1, IL23: Insulating layer
ML, ML11, ML12, ML21, ML22: Wiring layer
MP, MP1, MP2: Pad portion
VH, VH1, VH2: Via hole
VL, VL1, VL2: Via
CS: Side wall
PL: Passivation layer

What is claimed is:

1. A printed circuit board, comprising:
an insulating layer;
a wiring layer buried in the insulating layer; and
a pad portion protruding from the insulating layer in a height direction,
wherein the pad portion includes a first portion and a second portion disposed below the first portion in the height direction,
a width of the second portion is greater than that of the first portion of the pad portion in a plane direction perpendicular to the height direction,
a side wall of the second portion has a curved shape along the height direction, and
the side wall of the second portion is buried in the insulating layer.

2. The printed circuit board of claim 1, wherein:
the pad portion further includes a third portion disposed above the first portion in the height direction, and
a width of the third portion is greater than that of the first portion of the pad portion in the plane direction.

3. The printed circuit board of claim 2, wherein:
at least a portion of the first portion and the third portion of the pad portion protrude from the insulating layer in the height direction.

4. The printer circuit board of claim 3, wherein:
the side wall of the pad portion has a shape depressed inwardly of the pad portion along the height direction.

5. The printed circuit board of claim 1, wherein:
the insulating layer has a via hole overlapping the pad portion, and
the pad portion contacts a via disposed in the via hole.

6. The printed circuit board of claim 1, wherein:
the insulating layer includes a first insulating layer and a second insulating layer disposed below the first insulating layer,
the wiring layer includes a first wiring layer buried in the second insulating layer and a second wiring layer disposed below the second insulating layer,
the first insulating layer has a first via hole,
the second insulating layer has a second via hole,
the first wiring layer and the pad portion are connected to each other through a first via disposed in the first via hole, and
the first wiring layer and the second wiring layer are connected to each other through a second via disposed in the second via hole.

7. The printed circuit board of claim 6, further comprising:
a passivation layer disposed below the second insulating layer,
wherein the passivation layer exposes at least a portion of the second wiring layer.

8. The printed circuit board of claim 7, further comprising:
a surface treatment layer disposed above the pad portion.

9. The printed circuit board of claim 1, wherein:
the side wall of the pad portion has a shape depressed inwardly along the height direction.

10. A printed circuit board, comprising:
an insulating layer;
a wiring layer buried in the insulating layer; and
a pad portion protruding from the insulating layer in a height direction,
wherein the pad portion includes a first portion, a second portion disposed below the first portion in the height direction and buried in the insulating layer, and a third portion disposed above the first portion in the height direction and protruding from the insulating layer,
a width of the second portion is greater than that of the first portion of the pad portion in a plane direction perpendicular to the height direction, and
a width of the third portion is greater than that of the first portion of the pad portion in the plane direction.

11. The printed circuit board of claim 10, wherein:
the side wall of the pad portion has a shape depressed inwardly along the height direction.

12. A manufacturing method of a printed circuit board, comprising:
stacking a metal layer;
forming a photoresist pattern on the metal layer;
forming a pad portion by etching the metal layer using a photoresist pattern as an etch mask;
stacking an insulating layer burying the pad portion;
forming a wiring layer buried in the insulating layer; and
removing a portion of the insulating layer to expose a portion of the pad portion from the insulating layer in a height direction,
wherein the pad portion includes a first portion and a second portion disposed below the first portion in the height direction,
a width of the second portion is formed to be greater than that of the first portion of the pad portion in a plane direction perpendicular to the height direction,
a side wall of the second portion is formed to have a curved shape along the height direction, and
the side wall of the second portion is buried in the insulating layer.

13. The manufacturing method of claim 12, wherein:
at least a portion of the first portion of the pad portion protrudes from the insulating layer in the height direction.

14. The manufacturing method of claim 12, wherein:
the pad portion further includes a third portion disposed above the first portion in the height direction, and
a width of the third portion is formed to be greater than that of the first portion of the pad portion in the plane direction.

15. The manufacturing method of claim 14, wherein:
at least a portion of the first portion and the third portion of the pad portion protrudes from the insulating layer in the height direction.

16. The manufacturing method of claim 15, wherein:
the side wall of the pad portion is formed to have a shape depressed inwardly of the pad portion along the height direction.

17. The manufacturing method of claim 12, further comprising:
forming a via hole overlapping the pad portion in the insulating layer; and
forming a via in contact with the pad portion and disposed within the via hole.

18. The manufacturing method of claim 12, wherein:
the insulating layer includes a first insulating layer and a second insulating layer disposed below the first insulating layer, and
in the forming of the wiring layer, a first wiring layer buried in the second insulating layer is formed and a second wiring layer disposed below the second insulating layer is formed.

19. The manufacturing method of claim 18, further comprising:
forming a first via hole in the first insulating layer;
forming a second via hole in the second insulating layer;
connecting the first wiring layer and the pad portion and forming a first via disposed in the first via hole; and
connecting the first wiring layer and the second wiring layer and forming a second via disposed in the second via hole.

20. The manufacturing method of claim 12, wherein:
the side wall of the pad portion is formed to have a shape depressed inwardly along the height direction.
